(19) United States
(12) Patent Application Publication
(10) Pub. No.: US 2026/0026273 A1
(43) Pub. Date: Jan. 22, 2026

(54) OVERLAYER FILMS AND METHODS FOR ETCHING SILICON-CONTAINING MATERIALS USING A LOW TEMPERATURE DRY CHEMICAL ETCH PROCESS

(71) Applicants: Tokyo Electron Limited, Tokyo (JP); The Regents Of The University of Colorado, Denver, CO (US)

(72) Inventors: Hanna Paddubrouskaya, Austin, TX (US); Kate Abel, Austin, TX (US); Antonio Luis Pacheco Rotondaro, Austin, TX (US); Omid Zandi, Austin, TX (US); David Zywotko, Hillsboro, OR (US); Steven M. George, Boulder, CO (US)

(21) Appl. No.: 18/777,718

(22) Filed: Jul. 19, 2024

(51) Int. Cl. H01L 21/311

(52) U.S. Cl. CPC H01L 21/31116; H01L 21/31122

(57) ABSTRACT

Various embodiments of methods are provided that utilize an overlayer to accelerate etching of an underlayer provided on a semiconductor substrate. In the embodiments disclosed herein, an ultrathin (e.g., less than 2 nm) overlayer film is deposited onto an underlayer to enhance the local etch rate of (and selectivity to) the underlayer during a dry chemical etch process performed at low temperature (e.g., less than or equal to 100° C.). The overlayer film, which comprises a metal oxide or metal fluoride material, accelerates etching of the underlayer at temperatures below the threshold energy typically needed to enable chemical reactions on a bare underlayer surface by providing a medium for more effective chemical reactions at the surface of the underlayer.

### TECHNICAL FIELD

The present disclosure relates to the processing of semiconductor substrates. In particular, it provides novel overlayer films and methods for accelerating etching of a silicon-containing underlayer using a low-temperature dry chemical etch process.

### BACKGROUND

Semiconductor device formation typically involves a series of manufacturing techniques related to the formation, patterning, and removal of a number of layers of material on a substrate. During routine semiconductor fabrication, various materials formed on a substrate may be removed by patterned etching, chemical-mechanical polishing, as well as other techniques.

Selectivity and process controllability are major process requirements in etching, especially at nanoscale dimensions. In addition, etch processes are ideally damage-free, i.e., impose minimal chemical or physical damage to other device components during processing. However, achieving damage-free conditions is often challenging as etching is typically achieved by chemical reactions, which require a minimum thermal energy to occur. Thermal budget is, thus, a key factor in IC fabrication where a process step is allowed a limited temperature dose.

It is often desirable to perform etch processes at a temperature as low as possible. Low temperatures, however, usually mean slower chemical reaction rates, resulting in longer processing time. In a chemically controlled etch process, a threshold temperature is needed to enable the chemical reaction(s) driving the etch process. This limits the etch process to a certain process parameter space. Novel approaches that allow modification to the process parameter space are highly desired in IC fabrication technology. For example, novel approaches that extend the process window to lower temperatures, while maintaining acceptable throughput, would provide a major advancement in IC fabrication technology.

A variety of techniques are known for etching layers on a substrate, including dry etching and wet etching processes. Wet etch processes involve chemical reactions in a liquid phase. While liquid-phase etch processes continue to play a major role in IC fabrication, they are less desirable when forming narrow 3D spaces and high aspect-ratio (AR) features, due to fluid transport limitations.

Dry etch processes, which include plasma-based and thermal-based processes, are more commonly used for etching narrow 3D spaces and high-AR features. Plasma-based etch processes use ionized species to etch material through a combination of physical and chemical processes. Unfortunately, the high temperatures used during plasma etching may cause thermal damage and defects in surrounding areas of the substrate. In addition, the ion bombardment used to remove material during plasma etching can also remove portions of the overlying resist, leading to reduced etch sensitivity. Unlike plasma etching, dry thermal etching (otherwise referred to as dry chemical etching, vapor phase etching or gas phase etching) is purely chemical and usually offers a predictable chemistry. Dry chemical etching is, thus, of great interest for isotropic etching 3D narrow spaces and high-AR features. Examples of these applications include selective material etching in the fabrication of nanosheet gate-all-around (GAA) transistors and 3D NAND high AR features. In nanosheet transistors, for example, angstrom-level etch controllability and selectivity is required given that some dimensions are as small as a few nanometers. Additionally, nanosheet GAA structures have intricate narrow 3D features, where a dry chemical etch is preferred over wet or plasma methods.

Dry chemical etching, which uses a vapor phase (or gas phase) chemistry to etch a desired portion of the substrate, usually requires high temperatures (e.g., temperatures significantly greater than 100° C.) for several reasons. First, the dry chemical etch reactions in such processes are purely controlled by the thermodynamics and kinetics factors. The higher temperature used during dry chemical etching compensates for the absence of free energy contributions from solvation (in a wet etch process) or physical force (in a plasma etch process). Second, the etch products need to be volatilized to effect dry chemical etching. Higher temperatures ensure sufficient volatility for the etch products to leave the surface.

While dry chemical etch processes, such as atomic layer etching (ALE) and chemical vapor etching (CVE), are finding more use cases in the semiconductor industry, they typically suffer from low throughput. ALE is a selective etch process that provides very low throughput by removing material a few angstroms at a time in a cyclic manner. CVE, on the other hand, is a continuous etch process. Although CVE typically offers higher throughput compared to ALE, it is still a relatively slow etch process, especially at low temperature.

Despite the limitations noted above, dry chemical etching remains the most promising method of etching narrow 3D spaces and high AR features. New methods that increase the etch rate of such processes at lower temperatures would be desirable for high volume manufacturing. Extending the process window to lower temperature is not only beneficial from a thermal budget point of view, but could open new avenues to achieve etch selectivity as different materials have different reaction thermochemistry.

### SUMMARY

The present disclosure provides various embodiments of methods that utilize an overlayer to accelerate etching of an underlayer provided on a semiconductor substrate. In the embodiments disclosed herein, an ultrathin (e.g., less than 2 nm) overlayer film is deposited onto an underlayer to enhance the local etch rate of (and selectivity to) the underlayer during a dry chemical etch process performed at low temperature (e.g., less than or equal to 100° C.). The overlayer film accelerates etching of the underlayer at temperatures below the threshold energy typically needed to enable chemical reactions on a bare underlayer surface by providing a medium for more effective chemical reactions at the surface of the underlayer.

The material and deposition thickness of the overlayer film may generally be selected for a given underlayer material and etch chemistry overlayer. In some embodiments, the overlayer film disclosed herein may be used to accelerate etching of a wide variety of silicon-containing materials such as, for example, silicon dioxide (SiO₂) or silicon nitride (SiNx). In one example embodiment, an overlayer film comprising a metal oxide or metal fluoride material (e.g., Al₂O₃, Ga₂O₃, HfO₂, ZnO, ZrO₂, AlF₃, GaF₃, etc.) may be deposited onto a SiO₂ layer to enhance the local SiO₂ etch rate and selectivity during a dry chemical etch process (e.g., an ALE or CVE process) performed at low temperature (e.g., less than or equal to 100° C.).

According to one embodiment, a method is provided herein to process a semiconductor substrate. In general, the method may include: (a) providing the semiconductor substrate, the semiconductor substrate comprising a first layer to be etched; (b) depositing a second layer on the first layer, the second layer comprising a metal oxide or a metal fluoride material; and (c) exposing the semiconductor substrate to a gas-phase etchant and a process temperature ranging between 25-100° C. to etch the first layer underlying the second layer. In such a method, the second layer deposited on the first layer increases an etch rate at which the first layer is etched, compared to an etch rate achieved without the second layer deposited on the first layer.

The first layer and the second layer may each comprise a wide range of materials. In some embodiments, the first layer may contain silicon and the second layer may comprise a metal oxide or a metal fluoride material. In one example, the first layer may comprise silicon dioxide (SiO₂) or silicon nitride (SiN), and the second layer may comprise aluminum oxide (Al₂O₃), gallium oxide (Ga₂O₃), hafnium oxide (HfO₂), zinc oxide (ZnO), zirconium dioxide (ZrO₂), aluminum fluoride (AlF₃), gallium fluoride (GaF₃), hafnium tetrafluoride (HfF₄), zinc fluoride (ZnF₂) or zirconium tetrafluoride (ZrF₄). The second layer is a relatively thin metal oxide or metal fluoride overlayer, which is deposited onto the first layer (i.e., the underlayer to be etched). In some embodiments, the deposition thickness of the second layer may range between 0.15 nm and 1.5 nm. In some embodiments, the process temperature may be within a range of 40-80° C. during said exposing.

In some embodiments, the method may further include controlling the etch rate at which the first layer is etched by selecting a deposition thickness of the second layer and the process temperature used during said exposing. In one example, the etch rate of the first layer may be increased by increasing a deposition thickness of the second layer until a maximum deposition thickness is reached, after which the etch rate of the first layer decreases. In another example, the etch rate of the first layer may be increased by decreasing the process temperature, as long as the process temperature remains above a threshold temperature needed to enable etching.

In some embodiments, an aluminum oxide (Al₂O₃) layer having a deposition thickness of the Al₂O₃ layer ranges between 0.15 nm and 1.5 nm may be deposited on a silicon dioxide (SiO₂) layer before exposing the semiconductor substrate to a gas-phase mixture of hydrogen fluoride (HF) and water (H₂O) vapor and a process temperature ranging between 40-80° C. In such embodiments, the Al₂O₃ layer (i.e., the second layer) may increase the etch rate of the SiO₂ layer (i.e., the first layer) by providing a retention layer for HF and H₂O, the retention layer providing a medium for more efficient reaction with a surface of the SiO₂ layer. In some embodiments, the etch rate of the SiO₂ layer may range between 5 nanometers/minute (nm/min) and 25 nm/min. In one example embodiment, the deposition thickness of the Al₂O₃ layer may be approximately 1 nm, the process temperature may be approximately 60° C. and the etch rate of the SiO₂ layer may be approximately 25 nm/min.

According to another embodiment, a method is provided herein to pattern a semiconductor substrate. The method may generally include: (a) providing the semiconductor substrate, the semiconductor substrate comprising a first silicon-containing layer to be etched; (b) forming a patterned layer on the first silicon-containing layer, the patterned layer comprising a metal oxide or a metal fluoride material; and (c) exposing the semiconductor substrate to a gas-phase etchant and a process temperature ranging between 25-100° C. to etch portions of the first silicon-containing layer directly underlying the patterned layer to form a pattern of features within the first silicon-containing layer. In such a method, the patterned layer formed on the first silicon-containing layer increases an etch rate at which the portions of the first silicon-containing layer directly underlying the patterned layer are etched, compared to an etch rate achieved in other portions of the first silicon-containing layer not covered by the patterned layer.

The first silicon-containing layer and the patterned layer may each comprise a wide range of materials. In some embodiments, the first silicon-containing layer may comprise silicon dioxide (SiO₂) or silicon nitride (SiN), and the patterned layer comprises aluminum oxide (Al₂O₃), gallium oxide (Ga₂O₃), hafnium oxide (HfO₂), zinc oxide (ZnO), zirconium dioxide (ZrO₂), aluminum fluoride (AlF₃), gallium fluoride (GaF₃), hafnium tetrafluoride (HfF₄), zinc fluoride (ZnF₂) or zirconium tetrafluoride (ZrF₄). In some embodiments, the deposition thickness of the patterned layer may range between 0.15 nm and 1.5 nm, and the process temperature may be within a range of 40-80° C. during said exposing.

In some embodiment, the patterned layer deposited on the first silicon-containing layer increases the etch rate at which the portions of the first silicon-containing layer directly underlying the patterned layer are etched, compared to an etch rate achieved in a second silicon-containing layer exposed on the semiconductor substrate. For example, when the first silicon-containing layer comprises silicon dioxide (SiO₂), the second silicon-containing layer may include silicon (Si), silicon nitride (SiN) or silicon carbide (SIC).

As noted above and described further herein, the present disclosure provides various embodiments of processing systems and methods for processing semiconductor substrates. Of course, the order of discussion of the different steps as described herein has been presented for the sake of clarity. In general, these steps can be performed in any suitable order. Additionally, although each of the different features, techniques, configurations, etc., herein may be discussed in different places of this disclosure, it is intended that each of the concepts can be executed independently of each other or in combination with each other. Accordingly, the present invention can be embodied and viewed in many different ways.

Note that this Summary section does not specify every embodiment and/or incrementally novel aspect of the present disclosure or claimed inventions. Instead, the summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 is a flowchart diagram illustrating one embodiment of a method that utilizes the techniques described herein to process a semiconductor substrate.

FIG. 2A provides cross-sectional views through a semiconductor substrate having an overlayer formed on an underlayer to be etched, illustrating one embodiment of a process flow that utilizes the techniques described herein to increase the etch rate at which the underlayer is etched.

FIG. 2B provides cross-sectional views through a semiconductor substrate not having an overlayer formed on an underlayer to be etched, illustrating the slower etch rate achieved compared to the embodiment shown in FIG. 2A.

FIG. 2C is a magnified view illustrating a portion of the overlayer and underlayer shown in FIG. 2A.

FIG. 3 is a graph illustrating the effect of Al₂O₃ film thickness on the SiO₂ etch rate.

FIG. 4 is a graph illustrating the effect of Al₂O₃ film thickness on the SiO₂ etch rate and comparing the SiO₂ etch rate to etch rates achieved on other oxides.

FIG. 5 is a graph illustrating the effect of temperature on the SiO₂ etch rate.

FIG. 6 is a graph comparing the amount of SiO₂ etched on a SiO₂ layer comprising a 1 nm thick Al₂O₃ overlayer film to the amount of SiO₂ etched on a bare SiO₂ layer after exposing the substrates to 9 Torr H₂O and ˜6 Torr HF at 62° C. for 500 seconds.

FIG. 7 is a flowchart diagram illustrating one embodiment of a method that utilizes the techniques described herein to pattern a semiconductor substrate.

FIGS. 8A-8D are cross-sectional views through a semiconductor substrate having a patterned overlayer formed on an underlayer to be etched, illustrating one embodiment of a process flow that utilizes the techniques described herein to increase the etch rate of and selectivity to the portions of the underlayer directly underlying the patterned overlayer.

### DETAILED DESCRIPTION

The present disclosure provides various embodiments of methods that utilize an overlayer to accelerate etching of an underlayer provided on a semiconductor substrate. In the embodiments disclosed herein, an ultrathin (e.g., less than 2 nm) overlayer film is deposited onto an underlayer to enhance the local etch rate of (and selectivity to) the underlayer during a dry chemical etch process performed at low temperature (e.g., less than or equal to 100° C.). The overlayer film accelerates etching of the underlayer at temperatures below the threshold energy typically needed to enable chemical reactions on a bare underlayer surface by providing a medium for more effective chemical reactions at the surface of the underlayer.

The material and deposition thickness of the overlayer film may generally be selected for a given underlayer material and etch chemistry overlayer. In some embodiments, the overlayer film disclosed herein may be used to accelerate etching of a wide variety of silicon-containing materials such as, for example, silicon dioxide (SiO₂) or silicon nitride (SiNx). In one example embodiment, an overlayer film comprising a metal oxide or metal fluoride material (e.g., Al₂O₃, Ga₂O₃, HfO₂, ZnO, ZrO₂, AlF₃, GaF₃, etc.) may be deposited onto a SiO₂ layer to enhance the local SiO₂ etch rate and selectivity during a dry chemical etch process (e.g., an ALE or CVE process) performed at low temperature (e.g., less than or equal to 100° C.).

Various dry etching techniques have been used to etch SiO₂. Surface treatment with anhydrous hydrogen fluoride (HF) gas is one example of a vapor-phase etching technique that has been previously used to etch SiO₂. The chemical reaction of SiO₂ with anhydrous HF gas can be expressed as: SiO₂+4HF→SiF₄+2H₂O. While SiO₂ etching occurs in the presence of anhydrous HF gas, the chemical reaction rate (and thus, the SiO₂ etch rate) is extremely slow even at high temperatures (e.g., >600° C.).

Vapor-phase etching with a HF/H₂O gas mixture is another well-known method for etching SiO₂. Adding water vapor to the etchant gas accelerates the chemical reaction of SiO₂ by forming reactive HF₂⁻ species that enhance SiO₂ etching. The reactive HF₂⁻ species are formed via the reaction: 3H₂O+6HF→3HF₂⁻+3H₃O⁺. Once formed, the HF₂⁻ species etch SiO₂ via the reaction: 3HF₂⁺3H₃O⁺+SiO₂→2HF+SiF₄+5H₂O. H₂O is considered a catalyst in the method described above because H₂O is needed for HF₂⁻ formation. After the etching reaction begins, the additional H₂O generated by SiO₂ etching can sustain the reaction.

It is generally well-known that the SiO₂ etch rate is highly dependent on the HF/H₂O partial pressures, as well as the substrate temperature. A threshold pressure is needed to effect SiO₂ etching with a HF/H₂O gas mixture. This is attributed to the need for the formation of an H₂O condensation layer on the SiO₂ surface that provides a medium for HF reaction with the SiO₂ surface. The H₂O condensate layer provides a liquid-like medium where HF enriches and dissociates to form the HF₂⁻ species, which are known to be active etchants in SiO₂ etching with HF. Upon reaction with HF, SiO₂ ultimately converts to SiF₄, which is a volatile species. A threshold temperature is, therefore, necessary to volatize the reaction product and enable SiO₂ etching. However, higher temperatures (above 100° C.) defeat the vapor condensation necessary for the reaction to occur, as explained above. Due to this trade-off, vapor-phase etching of SiO₂ with HF/H₂O typically peaks around room temperature (˜25° C.), usually with much lower etch rates (e.g., several hundred nm/min) than those achieved in a liquid-phase etch process using concentrated HF solutions at room temperature (e.g., greater than 1000 nm/min), and drops significantly at process temperatures above ˜40° C. For example, conventional vapor-phase etching of bare SiO₂ may achieve an etch rate of only 2-3 nm/min at approximately 60° C., as discussed further below.

Photoresist materials have been previously used to accelerate SiO₂ etching in the presence of anhydrous HF gas. For example, U.S. Pat. No. 4,127,437 describes a process for etching SiO₂ using anhydrous HF vapor and an organic catalyst. In the '437 Patent, a negative photoresist material containing carbon and hydrogen, but no oxygen, is deposited onto a SiO₂ layer and used as a catalyst to activate the SiO₂ surface and make it susceptible to HF. The etch process disclosed in the '437 Patent is performed in a vacuum chamber at relatively low pressure (e.g., 3-7 torr) and high temperature (e.g., 150-200° C.). The etch rate achieved in such a process is not disclosed.

In a more recent study conducted by Sano et al. (“Atmospheric Gas-Phase Catalyst Etching of SiO₂ for Deep Microfabrication Using HF Gas and Pattered Photoresist,” published Apr. 23, 2024), a novolac-type photoresist is used as a catalyst in a high-temperature atmospheric HF gas-phase SiO₂ etching process. In order to provide deep, anisotropic SiO₂ etching, the study exposed a photoresist-covered area to anhydrous HF gas and high temperature conditions above 100° C. to prevent the adsorption of H₂O molecules (which serve as a reaction accelerator) onto the SiO₂ surface. The study found that the dry etching rate in the photoresist-covered area increased sharply when processing temperatures increased from 100 to 200° C. and reached a maximum of 1.3 μm/min at 250° C.

Recently, metal-assisted chemical etching (abbreviated as MacEtch or MACE) has been investigated as an anisotropic wet etching method for producing arrays of micro- and nanostructures in a variety of semiconductor substrates, including silicon (Si), silicon carbide (SiC), germanium (Ge), silicon germanium (SiGe), gallium arsenide (GaAs), gallium nitride (GaN), etc. MacEtch deposits a noble metal catalyst (such as gold (Au), platinum (Pt), palladium (Pd), silver (Ag), etc.) onto a substrate surface exposed to an etch solution containing an oxidant and an acid (or base) to induce local reduction and oxidation reactions on the substrate surface. An etch solution containing hydrogen peroxide (H₂O₂) and hydrofluoric acid (HF) is typically used to etch Si substrates. The noble metal catalyst deposited onto the substrate surface serves as a local cathode to catalyze the reduction of the oxidant, producing holes (h+) that are injected into the valence band of the substrate. The presence of the holes changes the oxidation state of the silicon underlying the noble metal catalyst and enables the oxidation and selective removal of silicon in the acidic etch solution. As the silicon is removed beneath the catalyst, it sinks and contacts unreacted material, continuing the reaction to form a negative image of the catalytic mask. This results in the removal of semiconductor materials without net consumption of the noble metal. Although the traditional MacEtch process enables anisotropic wet etching of semiconductor materials (such as Si), it is not suitable for selective etching of stable oxide materials, such as SiO₂.

The present disclosure improves upon conventional vapor-phase and wet etching techniques by providing novel overlayer films and methods for etching SiO₂ and other silicon-containing materials in a dry chemical etch process that uses much lower temperatures than previously described. In the embodiments disclosed herein, a metal oxide or metal fluoride overlayer film is deposited onto a SiO₂ layer and used as a catalyst when vapor-phase etching SiO₂ with a HF/H₂O gas mixture at low process temperature (ranging, e.g., between approximately 25° C. and 100° C.). As explained in more detail below, the metal oxide or metal fluoride overlayer film accelerates etching of the SiO₂ layer directly underlying the overlayer film by changing the thermodynamics and/or kinetics of the reactions taking place on the SiO₂ surface. Without limiting the disclosure to any one theory, it is suspected that the overlayer film may change the thermodynamics and/or kinetics of the surface reactions by: (a) providing a catalytic effect to initiate the etch reaction, (b) improving water vapor condensation by enhancing the adsorption of H₂O molecules at the interface between the overlayer film and the SiO₂ surface, and/or (c) providing an ultra-thin solvation layer that improves the kinetics of the reaction and allows for better product (e.g., SiF₄) volatilization. As a result, the novel overlayer films and methods disclosed herein achieve much higher SiO₂ etch rates (e.g., by an order of magnitude at the same temperature) than achieved in conventional SiO₂ vapor-phase etch processes.

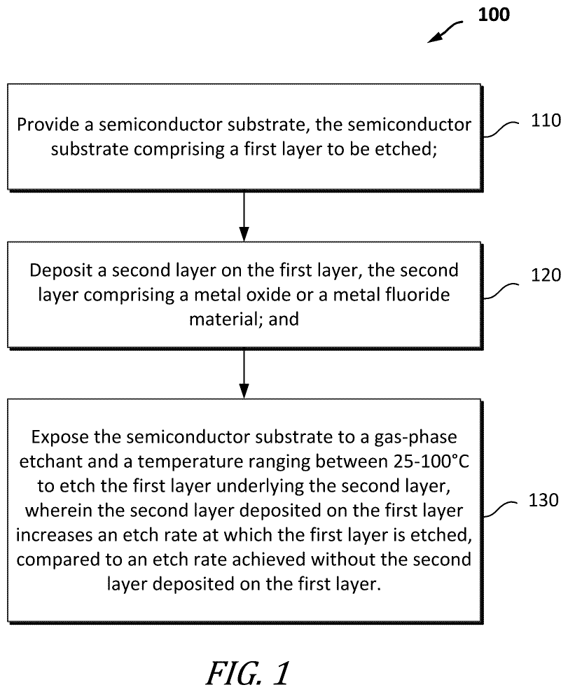

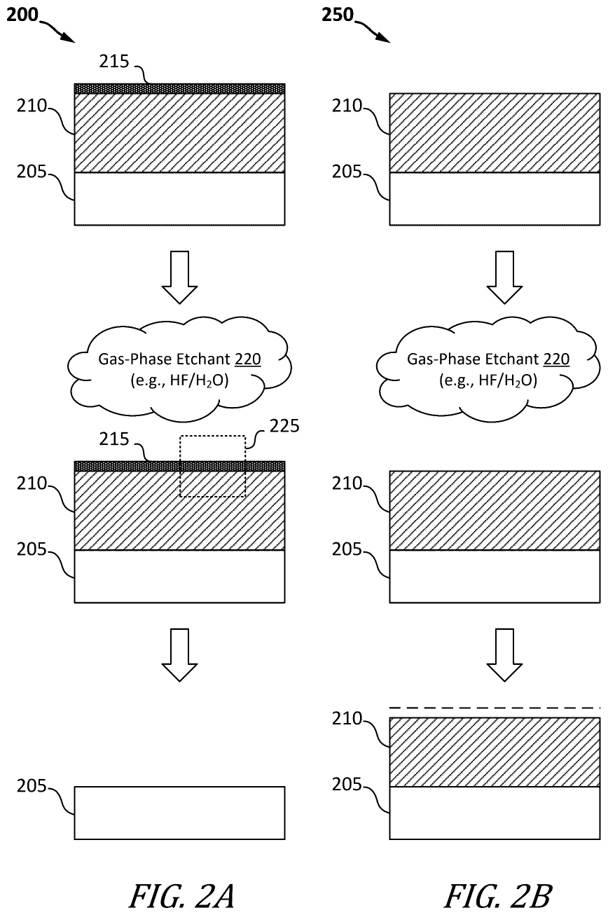

FIG. 1 illustrates one embodiment of a method 100 that utilizes the techniques disclosed herein to process a semiconductor substrate. More specifically, method 100 utilizes a metal oxide or metal fluoride overlayer film to accelerate etching of an underlayer provided on a semiconductor substrate. An example of a process flow 200 that utilizes the method 100 shown in FIG. 1 to increase the etch rate at which the underlayer is etched is shown in FIG. 2A.

It will be recognized that the embodiments of the method 100 and the process flow 200 are merely exemplary and additional methods and process flows may utilize the techniques disclosed herein. Further, additional processing steps may be added to the method 100 and/or the process flow 200, as the steps described are not intended to be exclusive. Moreover, the order of the steps is not limited to the order shown in the figures as different orders may occur and/or various steps may be performed in combination or at the same time.

As shown in FIGS. 1 and 2A, the method 100 and process flow 200 may begin by providing a semiconductor substrate 205 comprising a first layer 210 to be etched (in step 110) and depositing a second layer 215 on the first layer 210 (in step 120). The first layer 210 may contain silicon, in some embodiments. For example, the first layer 210 may be a silicon dioxide (SiO₂) layer, a silicon nitride (SiNx) layer or another silicon-containing layer. In the embodiments shown in FIGS. 1 and 2A, the second layer 215 is a metal oxide or a metal fluoride overlayer, which is deposited onto the first layer 210 (i.e., the underlayer to be etched). The second layer 215 may include a wide variety of metal oxide or metal fluoride materials such as, but not limited to, aluminum oxide (Al₂O₃), gallium oxide (Ga₂O₃), hafnium oxide (HfO₂), zinc oxide (ZnO), zirconium dioxide (ZrO₂), aluminum fluoride (AlF₃), gallium fluoride (GaF₃), hafnium tetrafluoride (HfF₄), zinc fluoride (ZnF₂), zirconium tetrafluoride (ZrF₄), etc.

Various deposition methods can be used to deposit the second layer 215 on the first layer 210 (in step 120) including, but not limited to, atomic layer deposition (ALD), pulsed laser deposition, chemical vapor deposition (CVD) and physical vapor deposition (PVD). ALD may be preferred, in some embodiments, due to the precision material engineering ability of ALD. Regardless of the particular deposition method used, the second layer 215 is preferably an ultra-thin overlayer film. The deposition thickness of the second layer 215 may be selected based on a variety of factors including, for example, the material composition of the second layer 215, the gas-phase etchant used to etch the first layer 210, the gas pressure and the process temperature. In some embodiments, the deposition thickness of the second layer 215 may range between 0.15 nm and 1.5 nm, as described in more detail below.

After the second layer 215 is deposited onto the first layer 210, the semiconductor substrate 205 is exposed to a gas-phase etchant 220 and a relatively low process temperature (ranging, e.g., between 25-100° C.) to etch the first layer 210 underlying the second layer 215 (in step 130). The gas-phase etchant 220 may generally include a mixture of fluorine-based gas and water vapor. In some embodiments, the semiconductor substrate 205 may be exposed to a gas-phase mixture of hydrogen fluoride (HF) and water (H₂O) vapor and a process temperature ranging between approximately 40° C. and 100° C. (in step 130) when the first layer 210 is a SiO₂ layer and the second layer 215 is an ultra-thin Al₂O₃ layer (ranging, e.g., between 0.15 nm and 1.5 nm). However, other gas-phase etchants 220 and process temperatures may be appropriate when etching other silicon-containing materials. Once a desired amount of the first layer 210 is removed by the gas-phase etchant 220, a different gas-phase etchant may be used to remove the second layer 215, as shown in FIG. 2A.

The second layer 215 deposited onto the first layer 210 (in step 120) increases the etch rate at which the first layer 210 is etched (in step 130), compared to an etch rate which would otherwise be achieved without the second layer 215 deposited on the first layer 210. For example, FIG. 2B illustrates an alternative process flow 250 in which a bare surface of the first layer 210 (i.e., a surface not covered by the second layer 215) is exposed to the gas-phase etchant 220 under the same process conditions (e.g., same etchant gas mixture, gas pressure, process temperature, etc.) used to etch the first layer 210 covered by the second layer 215 in the process flow 200 shown in FIG. 2A. In some embodiments, the second layer 215 deposited onto the first layer 210 (in step 120) may increase the etch rate of the first layer 210 by approximately 10 times (or more) compared to the etch rate achieved on the bare surface of the first layer 210 under the same process conditions.

The etch rate at which the first layer 210 is etched in step 130 is dependent on a variety of factors including, the material composition of the first layer 210 being etched, the material composition and deposition thickness of the second layer 215 deposited onto the first layer 210, the gas-phase etchant 220 used to etch the first layer 210, as well as the gas pressure and process temperature used. In some embodiments, the etch rate of the first layer 210 can be controlled by selecting a particular material composition and/or deposition thickness of the second layer 215 deposited in step 120 and/or the process temperature used in step 130.

In one embodiment, an ultra-thin Al₂O₃ layer having a deposition thickness ranging between 0.15 nm and 1.5 nm may be deposited onto a SiO₂ layer (in step 120) before the semiconductor substrate 205 is exposed to a gas-phase mixture of hydrogen fluoride (HF) and water (H₂O) vapor (in step 130) to etch the SiO₂ layer underlying the Al₂O₃ layer. The Al₂O₃ layer increases the etch rate of the SiO₂ layer by providing a retention layer for HF and H₂O, thereby providing a medium for more efficient reaction with the underlying SiO₂ surface. In one example, a semiconductor substrate having a 1 nm thick Al₂O₃ layer formed above and in contact with the SiO₂ layer may be exposed to an HF/H₂O gas mixture and a process temperature of about 60° C. in step 130 to achieve a SiO₂ etch rate of approximately 25 nm/min.

The ultra-thin Al₂O₃ layer deposited onto the SiO₂ layer (in step 120) may enhance etching of SiO₂ and other silicon-containing underlayers (in step 130) in a variety of ways. When low process temperatures (ranging, e.g., between 25-100° C.) are used in step 130, the HF and H₂O molecules within the Al₂O₃ layer may form a condensate layer 230 at the interface of the Al₂O₃ layer and the underlying SiO₂ surface as shown in box 225 of FIG. 2C (box 225 also being shown in FIG. 2A). As noted above, the condensate layer 230 formed at the interface provides a liquid-like medium in which HF enriches and dissociates to form the reactive HF₂ species, which enhance etching of the underlying SiO₂ surface to increase the etch rate of the SiO₂ layer. The Al₂O₃ layer may also increase the etch rate of the underlying SiO₂ layer by providing an ultra-thin solvation layer that improves the reaction efficiency at the SiO₂ surface and/or by providing a catalytic effect to initiate the etch process, as discussed further herein.

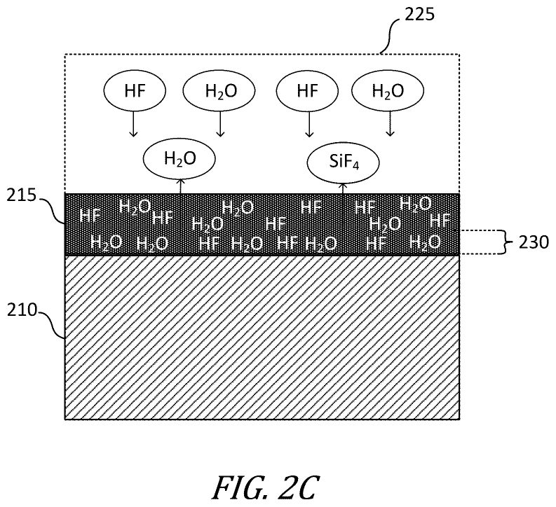

Etching experiments were performed to investigate the etch rate enhancement achieved by depositing an ultra-thin Al₂O₃ overlayer onto a SiO₂ layer before exposing the semiconductor substrate to an HF/H₂O gas-phase mixture to etch the SiO₂ layer underlying the Al₂O₃ overlayer. A first etching experiment was performed to investigate the effect of Al₂O₃ film thickness on the SiO₂ etch rate. The graph 300 shown in FIG. 3 depicts the amount of SiO₂ etched (the “SiO₂ Etched Thickness,” expressed in Å) after depositing Al₂O₃ films of various thickness (e.g., deposition thicknesses corresponding to 0-11 ALD cycles) on a SiO₂ layer formed on different substrates and exposing the substrates to 9 Torr H₂O and ˜6 Torr HF at 100° C. for 500 seconds.

As shown in the graph 300, the SiO₂ etched thickness increases with increasing number of Al₂O₃ ALD cycles until reaching a maximum etched thickness at approximately 6 Al₂O₃ ALD cycles (corresponding to an Al₂O₃ deposition thickness of approximately 1 nm). The SiO₂ etched thickness decreases for Al₂O₃ ALD cycles greater than 6 and is negligible after 11 Al₂O₃ ALD cycles. The increasing SiO₂ etch rate provided by the thinner Al₂O₃ films (ranging, e.g., between 1-6 ALD cycles) may be a result of the Al₂O₃ films increasing the number of HF₂ species needed for SiO₂ etching and/or acting as a catalyst for the HF₂ reaction with the SiO₂ surface. The reduction of the effect at thicker Al₂O₃ films is caused by the Al₂O₃ films acting as a barrier preventing the HF₂ species from reaching the SiO₂ surface.

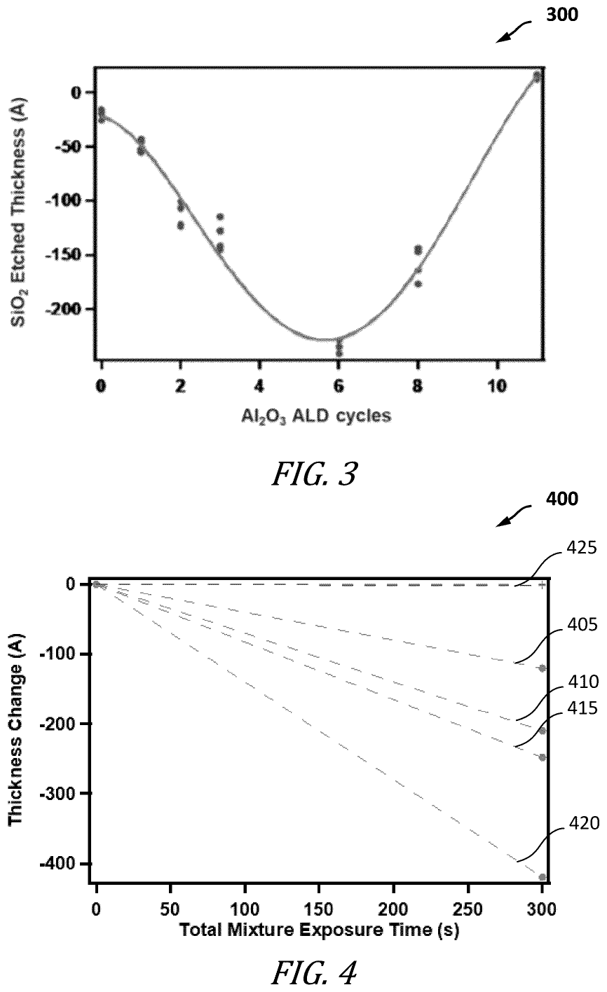

A second etching experiment was performed to investigate the effect of Al₂O₃ film thickness on the SiO₂ etch rate and compare the SiO₂ etch rate to etch rates achieved on other oxides. The graph 400 shown in FIG. 4 depicts the amount of SiO₂ etched (the “Thickness Change,” expressed in Å) after depositing Al₂O₃ films of various thickness (e.g., 1.5 Å in line 405, 3 Å in line 410, 4.5 Å in line 415 and 9 Å in line 420) on a SiO₂ layer formed on different substrates and exposing the substrates to 12 Torr H₂O and 8 Torr HF at 100° C. for 300 seconds. The graph 400 further depicts the amount of bare HfO₂, ZrO₂ and ZnO layers etched in line 425 using the same etch chemistry and process conditions. As shown in the graph 400, the HF/H₂O gas mixture selectively etches the SiO₂ layers covered by the Al₂O₃ films, while providing little to no etching on the bare HfO₂, ZrO₂ and ZnO layers. The amount of SiO₂ etched increases with Al₂O₃ film thickness (e.g., about 11.5 nm in line 405, 21 nm in line 410, 25 nm in line 415 and 41.5 nm in line 420), providing SiO₂ etch rates of about 2.3 nm/min, 4.2 nm/min, 5 nm/min and 8.2 nm/min, respectively.

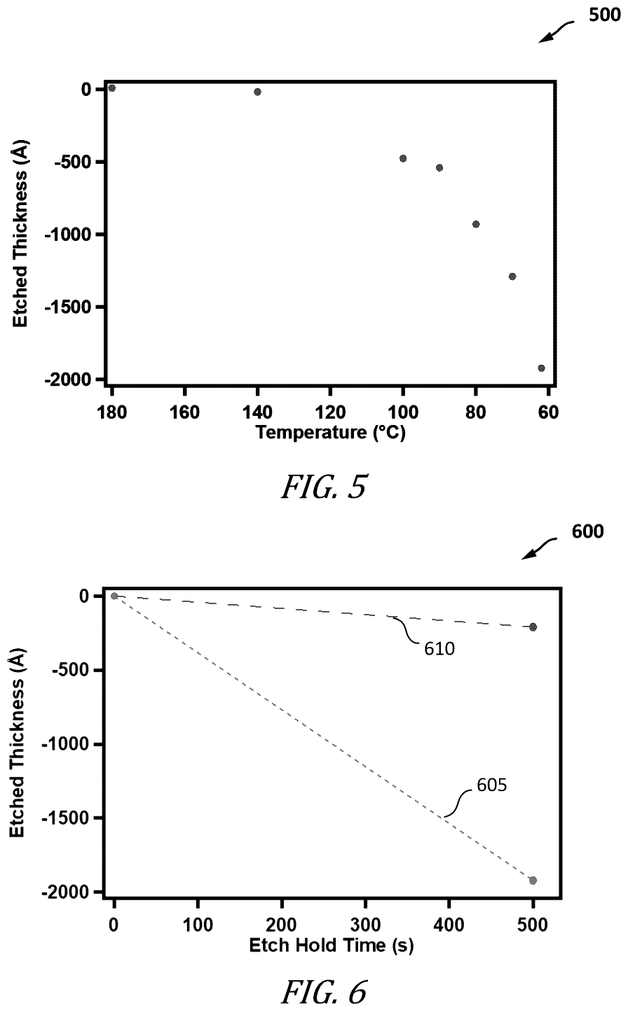

Another etching experiment was performed to investigate the effect of temperature on the SiO₂ etch rate. The graph 500 shown in FIG. 5 depicts the amount of SiO₂ etched (the “Etched Thickness,” expressed in Å) after depositing a 1 nm thick Al₂O₃ film on a SiO₂ layer formed on different substrates and exposing the substrates to 9 Torr H₂O and ˜6 Torr HF at various temperatures (e.g., 60° C. to 180° C.) for 1200 seconds. As shown in the graph 500, the SiO₂ etched thickness increases with decreasing temperature for process temperatures less than or equal to 100° C. The increased SiO₂ etch rate at lower temperatures (<100° C.) is likely due to the H₂O condensate layer formed at the interface between the Al₂O₃ film and the SiO₂ surface.

Although the lowest temperature depicted in the graph 500 is 60° C., the etch rate may be enhanced at even lower process temperature, as long as the temperature remains above a threshold temperature needed to enable etching. In some embodiments, a 1 nm thick Al₂O₃ film deposited onto a surface of a SiO₂ layer may increase the SiO₂ etch rate at process temperatures ranging between 25° C. to 100° C. However, process temperatures between 40° C. to 80° C. may be preferred, in some embodiments, to enable SiO₂ etch rates ranging between approximately 5 nm/min to 25 nm/min. In one example embodiment, a process temperature of approximately 60° C. may be used to provide a SiO₂ etch rate of approximately 25 nm/min, as discussed in more detail below.

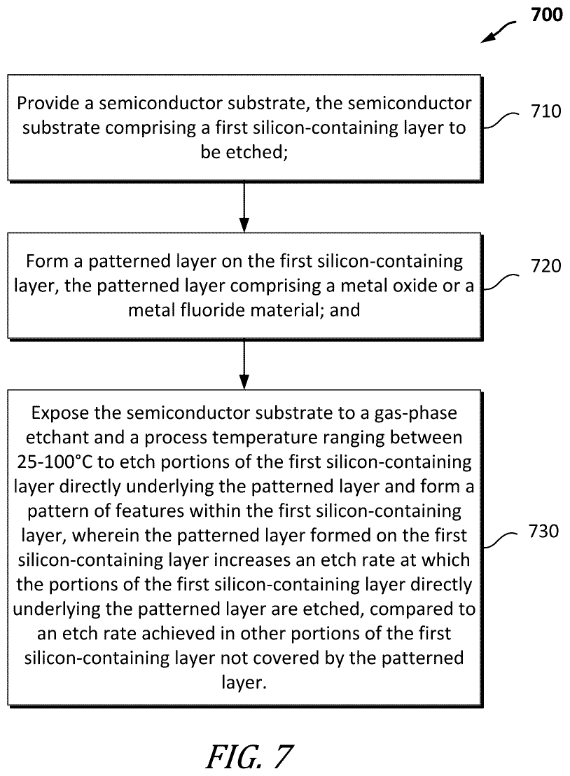

The graph 600 shown in FIG. 6 compares the amount of SiO₂ etched (the “Etched Thickness,” expressed in Å) on a SiO₂ layer comprising a 1 nm thick Al₂O₃ overlayer film (line 605) to the amount of SiO₂ etched on a bare SiO₂ layer (line 610) after exposing the substrates to 9 Torr H₂O and ˜6 Torr HF at 62° C. for 500 seconds. As shown in the graph 600, the Al₂O₃ overlayer film provides a SiO₂ etch rate of approximately 25 nm/min, which is approximately 10 times greater than the etch rate (e.g., 2-3 nm/min) achieved on the bare SiO₂ layer. The etch enhancement shown in FIG. 6 can be attributed to the Al₂O₃ overlayer film acting as a retention layer for HF/H₂O, thus providing a medium for more efficient reaction with the SiO₂ surface.

Although not depicted herein, similar results were observed for metal fluoride overlayer films (such as AlF₃) deposited on SiO₂. The mechanism of SiO₂ CVE enhancement by an AlFs overlayer is expected to be largely similar to that of Al₂O₃. Similar results were also observed for SiNx etching, although the CVE enhancement was more significant for SiO₂ than SiNx. It is, therefore, expected that a desired etch rate can be achieved for a wide variety of silicon-containing materials by optimizing the process parameters for these materials.

In the present disclosure, an ultrathin (e.g., less than 2 nm) metal oxide or metal fluoride overlayer film is deposited onto a silicon-containing underlayer to enhance the etch rate of and selectivity to the underlayer during a low-temperature (<100° C.) dry chemical etch process. As noted above, the metal oxide or metal fluoride overlayer film may enhance etching of SiO₂ and other silicon-containing underlayers in a variety of ways. First, the metal oxide or metal fluoride overlayer film may improve water condensation by enhancing water adsorption at the interface between the overlayer film and the underlying SiO₂ surface. Amphoteric Al₂O₃, in particular, provides a higher capacity and affinity for molecular water adsorption. Al₂O₃ and other thin ALD oxide films can also provide a high surface area for reactant adsorption, thus providing more effective water condensation at the SiO₂ surface. The metal oxide or metal fluoride overlayer film may also improve the reaction efficiency at the SiO₂ surface by providing a solvent-like medium for the reactants and reaction products. An ultrathin solvation layer not only improves the kinetics of the reaction, but also allows for better product (e.g., SiF₄) volatilization. The etch rate enhancement provided by the overlayer film can also be catalytic. For example, Al₂O₃ partially or entirely converts to AlF₃ upon conversion to HF. AlFs not only adsorbs HF, but also stabilizes the reaction transition states during chemical vapor etching (CVE), e.g., through hydrogen bonding. This pathway is consistent with HF₂ being a reactive species for etching SiO₂. Such catalytic effect can be key to initiate the etch reaction on the SiO₂ surface(s) covered by the metal oxide or metal fluoride overlayer film.

The metal oxide or metal fluoride overlayer film disclosed herein extends the process parameter space of vapor phase etching of silicon-containing materials to lower temperatures (ranging, e.g., between 25-100° C.) by altering the thermochemistry and kinetics of the surface phenomena. Dry chemical etch reactions usually require much higher temperatures (e.g., temperatures significantly greater than 100° C.) due to the lack of solvation free energy. A precisely engineered solvation layer (imparted by the overlayer film) compensates for this factor, while still allowing the techniques described herein to benefit from the advantages of dry chemical processing. By carefully designing an overlayer film for a given surface to be etched, the method 100 shown in FIG. 1 and process flow 200 shown in FIG. 2A can be used to extend to the process parameter space for other etch chemistry/material combinations.

The overlayer film disclosed herein improves upon other dry etching accelerators (e.g., positive/negative tone photoresist materials) by enhancing etching of silicon-containing materials at significantly lower process temperature. Enabling etching at lower temperature allows for damage-free etching in cases where the thermal budget is limited. In addition to enhancing etching at low temperature, the overlayer film disclosed herein enables a new pathway to achieve dry etch selectivity. In some embodiments, the SiO₂ etch rate (and selectivity) can be adjusted in a SiO₂ CVE process by controlling the thickness of the overlayer film deposited onto the SiO₂ surface and/or the process temperature used. For example, the SiO₂ etch rate can be increased by: (a) increasing the thickness of the overlayer film (up to a certain point), and/or (b) decreasing the process temperature (up to a certain point). In some embodiments, a combination of overlayer film thickness and process temperature can be used to provide process tunability. In other embodiments, a variable thickness overlay film may be used to enable a feed-forward corrective etch of an underlying silicon-containing layer.

Since the overlayer film has little to no effect on the etch rate of other materials provided on the semiconductor substrate, the overlayer film can also be used to enhance CVE of one material (e.g., SiO₂) while suppressing etching of another silicon-containing material (e.g., SiNx, SiC, etc.) or another material entirely. Additional selectivity can be achieved by selectively forming an overlayer film pattern on a material of interest using area selective deposition (ASD) techniques. Once the overlayer film pattern is formed on the material of interest, the material directly underlying the overlayer film pattern can be etched at higher selectivity than the rest of the substrate. This strategy can be applied in various ways to enable selective processing of a wide variety of materials.

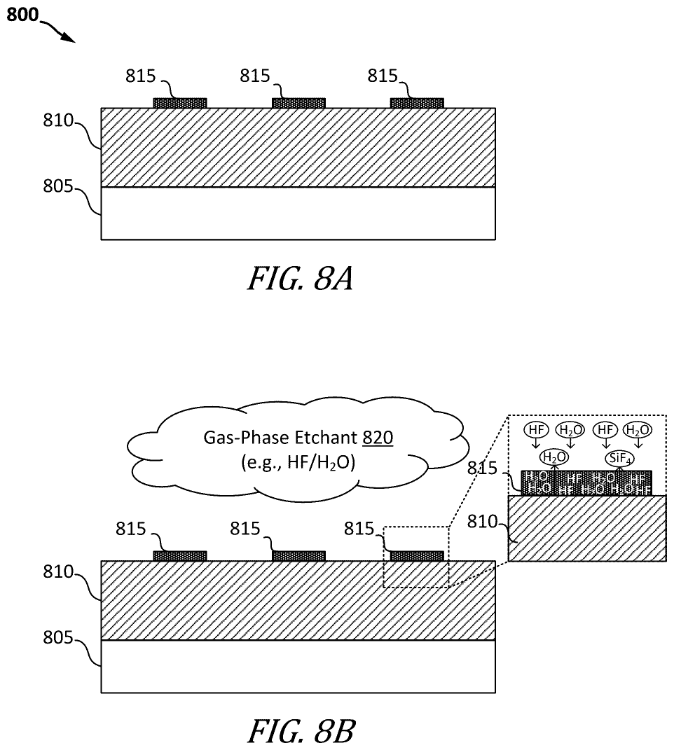

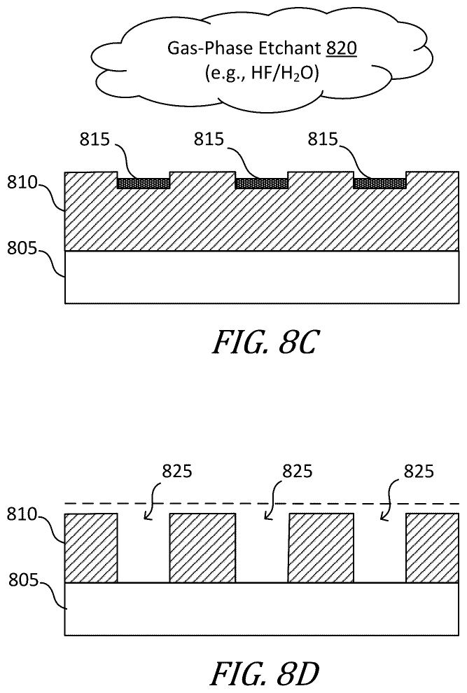

FIG. 7 illustrates one embodiment of a method 700 that utilizes the techniques described herein to pattern a semiconductor substrate. More specifically, method 700 utilizes a patterned layer of metal oxide or metal fluoride material to accelerate etching of a silicon-containing underlayer provided on a semiconductor substrate. An example a process flow 800 that utilizes the method 700 shown in FIG. 7 to increase the etch rate at which the covered portions of the silicon-containing underlayer are etched is shown in FIGS. 8A-8D.

It will be recognized that the embodiments of the method 700 and the process flow 800 are merely exemplary and additional methods and process flows may utilize the techniques disclosed herein. Further, additional processing steps may be added to the method 700 and/or the process flow 800, as the steps described are not intended to be exclusive. Moreover, the order of the steps is not limited to the order shown in the figures as different orders may occur and/or various steps may be performed in combination or at the same time.

As shown in FIGS. 7 and 8A, the method 700 and process flow 800 may begin by providing a semiconductor substrate 805 comprising a first silicon-containing layer 810 to be etched (in step 710) and forming a patterned layer 815 on the first silicon-containing layer 810 (in step 720). Like the previous embodiment, the first silicon-containing layer 810 may be a silicon dioxide (SiO₂) layer, a silicon nitride (SiNx) layer or another silicon-containing layer. In the embodiments shown in FIGS. 7 and 8A, the patterned layer 815 comprises a metal oxide or a metal fluoride material, which is deposited onto the first silicon-containing layer 810 (i.e., the underlayer to be etched) using one of a wide variety of deposition techniques (e.g., ALD, CVD, PVD, etc.). Examples of metal oxide or metal fluoride materials that may be used to form the patterned layer 815 are discussed above. In one example embodiment, the patterned layer 815 may include an ultra-thin Al₂O₃ layer having a deposition thickness ranging, e.g., between 0.15 nm and 1.5 nm.

As shown in FIGS. 7 and 8B-8D, the semiconductor substrate 805 is exposed to a gas-phase etchant 820 and a process temperature ranging between 25-100° C. to etch portions of the first silicon-containing layer 810 directly underlying the patterned layer 815 to form a pattern of features 825 within the first silicon-containing layer 810 (in step 730). In some embodiments, the semiconductor substrate 805 may be exposed to a gas-phase mixture of hydrogen fluoride (HF) and water (H₂O) vapor and a process temperature ranging between approximately 40° C. and 80° C. (in step 730) when the first silicon-containing layer 810 is a SiO₂ layer and the patterned layer 815 comprises an ultra-thin Al₂O₃ layer (having a deposition thickness ranging, e.g., between 0.15 nm and 1.5 nm). However, other gas-phase etchants 820 and process temperatures may be appropriate when etching other silicon-containing materials and/or patterned layer thicknesses.

The patterned layer 815 formed on the first silicon-containing layer 810 (in step 720) increases the etch rate at which the portions of the first silicon-containing layer 810 directly underlying the patterned layer 815 are etched (in step 730), compared to an etch rate achieved in other portions of the first silicon-containing layer 810 not covered by the patterned layer 815. When low process temperatures (ranging, e.g., between 25-100° C.) are used in step 730, the HF and H₂O molecules pass through the patterned layer 815, as shown in FIG. 8B, to alter the thermodynamics and/or kinetics of the surface reactions taking place at the interface between patterned layer 815 and portions of the first silicon-containing layer 810 directly underlying the patterned layer 815. For example, the patterned layer 815 may alter the thermodynamics and/or kinetics of the surface reactions by: (a) providing a catalytic effect to initiate the etch reaction, (b) improving water vapor condensation by enhancing the adsorption of H₂O molecules at the interface, and/or (c) improving the kinetics of the reaction and allowing better product (e.g., SiF₄) volatilization. One or more of these effects may cause the portions of the first silicon-containing layer 810 directly underlying the patterned layer 815 to be etched faster than portions of the first silicon-containing layer 810 not covered by the patterned layer 815 to form the pattern of features 825 within the first silicon-containing layer 810, as shown in FIGS. 8C-8D. Once a desired amount of the first silicon-containing layer 810 is removed, a different etch chemistry may be used to remove the patterned layer 815, as shown in FIG. 8D.

The method 700 shown in FIG. 7 and the process flow 800 shown in FIGS. 8A-8D utilize precision surface modification to locally enhance the etch rate and selectivity of a silicon-containing layer. In the embodiments shown in FIGS. 7 and 8, ASD techniques are used to modify the surface of a silicon-containing layer (such as, e.g., Si, SiO₂, SiNx, etc.) by selectively depositing a patterned layer 815 comprising a metal oxide or metal fluoride material on the silicon-containing surface. The metal oxide or metal fluoride patterned layer 815 enhances the local etch rate in the portions of the silicon-containing layer directly underlying the pattern to provide selective dry chemical etch processing of silicon-containing materials. This approach could enable many selective, dry chemical etch processes. For example, the method 700 and process flow 800 could be used to form a wide variety of patterns in a silicon-containing layer, or etch narrow 3D spaces or high AR features (such as deep holes or trenches) in a relatively thick silicon-containing layer. Example applications include, but are not limited to, the front and back end of integrated circuit (IC) and microelectromechanical (MEMS) device fabrication.

In some embodiments, the metal oxide or metal fluoride pattern can be used to enhance etching of one silicon-containing material, while suppressing etching on another silicon-containing material formed on the same substrate. For example, a patterned layer comprising a metal oxide or metal fluoride material (such as, e.g., Al₂O₃, Ga₂O₃, HfO₂, ZnO, ZrO₂, AlF₃, GaF₃, HfF₄, ZnF₂, ZrF₄, etc.) can be deposited on a first silicon-containing layer (e.g., a SiO₂ layer) to increase the etch rate at which the portions of the first silicon-containing layer directly underlying the patterned layer are etched, compared to an etch rate achieved in a second silicon-containing layer (e.g., a Si, SiNx, SiC, etc. layer) exposed on the same substrate.

The embodiments disclosed herein provide a novel approach to achieving selectivity in dry chemical etch processes (e.g., CVE and ALE) used to etch Si-based materials and provide numerous advantages. As noted above, for example, the metal oxide or metal fluoride overlay films described herein locally enhance the etch rate of an underlying silicon-containing layer (e.g., a SiO₂ layer), providing orders of magnitude higher (e.g., 10× or more) dry chemical etch rates than achieved on bare oxide surfaces (e.g., bare SiO₂, HfO₂, ZrO₂ and ZnO surfaces). A sufficiently high etch rate is beneficial when a large amount of material needs to be removed, such as forming deep holes or trenches in a silicon-containing layer, or fully removing portions of a substrate. The enhanced etch rate provided by the metal oxide or metal fluoride overlay films disclosed herein provides further advantages of low chemical consumption and high throughput. High throughput dry chemical etching can offer an alternative method to traditional wet or plasma etching methods. Etch selectivity is further enhanced in the embodiments disclosed herein by using ASD techniques to form a metal oxide or metal fluoride pattern on a silicon-containing layer to locally enhance the etch rate in the portions of the silicon-containing layer directly underlying the pattern.

In addition to the advantages described above, the embodiments disclosed herein can be implemented on existing fabrication equipment. For example, the metal oxide or metal fluoride overlayer film (or pattern) can be deposited and removed in-situ in a hybrid ALD/ALE or ALD/CVE tool. While ex-situ overlayer formation can also be achieved using a multi-chamber ALD/ALE or ALD/CVE tool, it may be less desirable depending on the fab infrastructure. The embodiments disclosed herein can also be used to expand ALE and CVE tool process capabilities and process windows. As noted above, the metal oxide or metal fluoride overlay film (or pattern) enables dry chemical etching of Si-based materials (such as Si, SiO₂, SiNx, etc.) at low process temperature (e.g., temperatures ranging between 25-100° C.). This may offer additional benefits in cases where thermal budget is limited, or damage is a concern. In some cases, the embodiments disclosed herein can be used as an alternative to deep reactive ion etching (RIE) where damage and cost of ownership of the process are desired to be minimized.

Extending the process window to lower temperatures is not only beneficial from a thermal budget point of view, it can also open new avenues to achieve etch selectivity since different materials have different reaction thermochemistry. In addition, providing an overlay film that enables low-temperature dry chemical etching of Si-based materials represents a distinct advantage over traditional high-temperature dry chemical etch methods as it effectively extends the process parameter space to temperatures where the reactions would not otherwise occur.

Systems and methods for processing a semiconductor substrate are described in various embodiments. The term “semiconductor substrate” or “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

The substrate may also include any material portion or structure of a device, particularly a semiconductor or other electronics device, and may, for example, be a base substrate structure, such as a semiconductor substrate or a layer on or overlying a base substrate structure. Thus, the term “substrate” is not intended to be limited to any particular base structure, underlying layer or overlying layer, patterned layer or unpatterned layer, but rather, is contemplated to include any such layer or base structure, and any combination of layers and/or base structures.

It is noted that various deposition processes can be used to form one or more of the material layers shown and described herein. For example, one or more depositions can be implemented using chemical vapor deposition (CVD), plasma enhanced CVD (PECVD), physical vapor deposition (PVD), atomic layer deposition (ALD), and/or other deposition processes. In one example ALD deposition process, a gas mixture comprising various metals, along with oxygen or fluorine, can be used to deposit a metal oxide or metal fluoride overlayer film on a silicon-containing layer. In one example embodiment, an aluminum oxide (Al₂O₃) can be deposited via CVD using a gas mixture comprising aluminum trichloride (AlCl₃), an oxygen source (e.g., oxygen or carbon dioxide) and hydrogen (H₂) optionally in combination with one or more dilution gases (e.g., argon, nitrogen, etc.) at a variety of pressure, power, flow, and temperature conditions. In another approach, ALD deposition using alternating exposure of the surface to trimethylaluminum and water may be used.

It is further noted that various etch processes can be used to etch one or more of the material layers shown and described herein. For example, a chemical vapor etching (CVE) or atomic layer etching (ALE) process may be used to etch the silicon-containing layer underlying the metal oxide or metal fluoride overlayer film. In one example CVE etch process, a gas mixture comprising a fluorine-based etchant and water vapor can be used to etch a silicon-containing layer. The gas mixture may include, but is not limited to, hydrogen fluoride (HF), water (H₂O) vapor and other fluorine-based chemistries optionally in combination with one or more dilution gases (e.g., argon, nitrogen, etc.) at a variety of pressure, power, flow and temperature conditions. As noted above, the process temperature used during the etch process is generally less than 100° C., more preferably between 40° C. to 80° C., and in at least one embodiment, is approximately 60° C.

Other operating variables for process steps can also be adjusted to control the various deposition and/or etch processes described herein. The operating variables may include, for example, the chamber temperature, chamber pressure, flowrates of gases, types of gases, and/or other operating variables for the processing steps. Variations can also be implemented while still taking advantage of the techniques described herein.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the methods described herein will be apparent to those skilled in the art in view of this description. It will be recognized, therefore, that the described methods are not limited by these example arrangements. It is to be understood that the forms of the methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method for processing a semiconductor substrate, the method comprising:
providing the semiconductor substrate, the semiconductor substrate comprising a first layer to be etched;
depositing a second layer on the first layer, the second layer comprising a metal oxide or a metal fluoride material; and
exposing the semiconductor substrate to a gas-phase etchant and a process temperature ranging between 25-100° C. to etch the first layer underlying the second layer, wherein the second layer deposited on the first layer increases an etch rate at which the first layer is etched, compared to an etch rate achieved without the second layer deposited on the first layer.

2. The method of claim 1, wherein the first layer contains silicon.

3. The method of claim 2, wherein the first layer comprises silicon dioxide (SiO₂) or silicon nitride (SIN).

4. The method of claim 2, wherein the second layer comprises aluminum oxide (Al₂O₃), gallium oxide (Ga₂O₃), hafnium oxide (HfO₂), zinc oxide (ZnO), zirconium dioxide (ZrO₂), aluminum fluoride (AlF₃), gallium fluoride (GaF₃), hafnium tetrafluoride (HfF₄), zinc fluoride (ZnF₂), or zirconium tetrafluoride (ZrF₄).

5. The method of claim 2, wherein a deposition thickness of the second layer ranges between 0.15 nm and 1.5 nm.

6. The method of claim 2, wherein the process temperature is within a range of 40-80° C. during said exposing.

7. The method of claim 1, further comprising controlling the etch rate at which the first layer is etched by selecting a deposition thickness of the second layer and the process temperature used during said exposing.

8. The method of claim 7, wherein said controlling the etch rate at which the first layer is etched comprises increasing the etch rate of the first layer by increasing a deposition thickness of the second layer until a maximum deposition thickness is reached, after which the etch rate of the first layer decreases.

9. The method of claim 7, wherein said controlling the etch rate at which the first layer is etched comprises increasing the etch rate of the first layer by decreasing the process temperature, as long as the process temperature remains above a threshold temperature needed to enable etching.

10. The method of claim 1, wherein said depositing the second layer on the first layer comprises depositing an aluminum oxide (Al₂O₃) layer on a silicon dioxide (SiO₂) layer, and wherein a deposition thickness of the Al₂O₃ layer ranges between 0.15 nm and 1.5 nm.

11. The method of claim 10, wherein said exposing the semiconductor substrate comprises exposing the semiconductor substrate to a gas-phase mixture of hydrogen fluoride (HF) and water (H₂O) vapor and a process temperature ranging between 40-80° C., wherein the Al₂O₃ layer increases the etch rate of the SiO₂ layer by providing a retention layer for HF and H₂O, the retention layer providing a medium for more efficient reaction with a surface of the SiO₂ layer.

12. The method of claim 11, wherein the etch rate of the SiO₂ layer ranges between 5 nanometers/minute (nm/min) and 25 nm/min.

13. The method of claim 11, wherein the deposition thickness of the Al₂O₃ layer is approximately 1 nm, the process temperature is approximately 60° C. and the etch rate of the SiO₂ layer is approximately 25 nm/min.

14. A method for patterning a semiconductor substrate, the method comprising:
providing the semiconductor substrate, the semiconductor substrate comprising a first silicon-containing layer to be etched;
forming a patterned layer on the first silicon-containing layer, the patterned layer comprising a metal oxide or a metal fluoride material; and
exposing the semiconductor substrate to a gas-phase etchant and a process temperature ranging between 25-100° C. to etch portions of the first silicon-containing layer directly underlying the patterned layer to form a pattern of features within the first silicon-containing layer, wherein the patterned layer formed on the first silicon-containing layer increases an etch rate at which the portions of the first silicon-containing layer directly underlying the patterned layer are etched, compared to an etch rate achieved in other portions of the first silicon-containing layer not covered by the patterned layer.

15. The method of claim 14, wherein the first silicon-containing layer comprises silicon dioxide (SiO₂) or silicon nitride (SIN).

16. The method of claim 14, wherein the patterned layer comprises aluminum oxide (Al₂O₃), gallium oxide (Ga₂O₃), hafnium oxide (HfO₂), zinc oxide (ZnO), zirconium dioxide (ZrO₂), aluminum fluoride (AlF₃), gallium fluoride (GaF₃), hafnium tetrafluoride (HfF₄), zinc fluoride (ZnF₂), or zirconium tetrafluoride (ZrF₄).

17. The method of claim 14, wherein a deposition thickness of the patterned layer ranges between 0.15 nm and 1.5 nm.

18. The method of claim 14, wherein the process temperature is within a range of 40-80° C. during said exposing.

19. The method of claim 14, wherein the patterned layer deposited on the first silicon-containing layer increases the etch rate at which the portions of the first silicon-containing layer directly underlying the patterned layer are etched, compared to an etch rate achieved in a second silicon-containing layer exposed on the semiconductor substrate.

20. The method of claim 19, wherein the first silicon-containing layer comprises silicon dioxide (SiO₂) and the second silicon-containing layer comprises silicon (Si), silicon nitride (SiN) or silicon carbide (SiC).
